(19) United States
(12) Patent Application Publication
(10) Pub. No.: US 2025/0176403 A1
(43) Pub. Date: May 29, 2025

(54) DISPLAY DEVICE

(71) Applicant: LG DISPLAY CO., LTD., Seoul (KR)

(72) Inventors: Byeongcheol LEE, Paju-si (KR); Chungoan SEO, Paju-si (KR)

(73) Assignee: LG DISPLAY CO., LTD., Seoul (KR)

(21) Appl. No.: 18/786,420

(22) Filed: Jul. 26, 2024

(30) Foreign Application Priority Data
Nov. 23, 2023 (KR) 10-2023-0163910

(51) Int. Cl. H10K 59/80

(52) U.S. Cl. CPC H10K 59/871

(57) ABSTRACT

A display device includes a display panel configured to include a display area and a pad area around the display area; a printed circuit film configured to be attached to the pad area of the display panel; a cover layer configured to be disposed above the display panel and to overlap the printed circuit film; and a bonding layer configured to bond the display panel and the cover layer. The printed circuit film and the bonding layer have a spaced space between each other in a planar view. A thickness of the cover layer that overlaps the printed circuit film has a size between a thickness of the cover layer in the spaced space and a thickness of the cover layer on the bonding layer.

### CROSS-REFERENCE TO RELATED APPLICATIONS

The present application claims the benefit of priority to Korean Patent Application No. 10-2023-0163910, filed Nov. 23, 2023, the entire contents of which is incorporated herein for all purposes by this reference.

### BACKGROUND

### Technical Field

The present disclosure relates to a display device.

### Discussion of the Related Art

With the development of the information society, various demands for a display device for displaying images are increasing. Various types of display devices such as a liquid crystal display, an organic light emitting diode display, etc., are being used.

The organic light emitting display device among the display devices emits light by itself. Compared to the liquid crystal display device, the organic light emitting display device has a larger viewing angle, a more excellent contrast ratio, etc., and requires no separate backlight, so that it can be lighter and thinner and is advantageous in terms of power consumption. Also, the organic light emitting display device can be driven at direct current low voltage, and has a rapid response speed and a lower manufacturing cost.

The display device may include a display panel, a printed circuit film which provides an external signal to the display panel, and a cover layer which is on the display panel and protects the display panel.

### SUMMARY

Accordingly, embodiments of the present disclosure are directed to a display device that substantially obviates one or more of the problems due to limitations and disadvantages of the related art.

An aspect of the present disclosure is to provide a display device capable of compensating for a step difference formed between the cover layer and the members below the cover layer.

Another aspect of the present disclosure is to provide a display device which has an excellent rigidity against external impact by filling the rigidity weak section of the display device.

Another aspect of the present disclosure is to provide a display device of which the process can be simplified by omitting separate processes for filling a gap formed between the cover layer and the members below the cover layer.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises: a display panel configured to include a display area and a pad area around the display area; a printed circuit film configured to be attached to the pad area of the display panel; a cover layer configured to be disposed above the display panel and to overlap the printed circuit film; and a bonding layer configured to bond the display panel and the cover layer. The printed circuit film and the bonding layer have a spaced space between each other in a planar view. A thickness of the cover layer that overlaps the printed circuit film has a size between a thickness of the cover layer in the spaced space and a thickness of the cover layer on the bonding layer.

In another aspect, a display device comprises: a display panel configured to include a display area and a pad area around the display area; a printed circuit film configured to be attached to the pad area of the display panel; a cover layer configured to be disposed above the display panel and to overlap the printed circuit film; and a bonding layer configured to bond the display panel and the cover layer. A thickness of the cover layer varies depending on the areas.

Other details of the embodiments are included in the detailed description and drawings.

According to the display device according to the embodiments, the thickness of the cover layer may vary depending on areas in consideration of the spaced distance of the spaced space formed between the cover layer and the members disposed below the cover layer. Due to the cover layer of which the thickness varies depending on areas, the spaced space between the cover layer and the members below the cover layer can be filled. The spaced space between the cover layer and the members below the cover layer is very vulnerable to external impact, which causes physical damage to the cover layer. However, according to the display device according to the embodiments, due to the cover layer of which the thickness varies depending on areas, the spaced space between the cover layer and the members below the cover layer is filled, so that the rigidity against external impact can be improved.

Also, according to the display device according to the embodiments, a separate gap fill process for filling the spaced space between the cover layer and the members below the cover layer can be omitted, so that the process can be significantly simplified.

Also, the display device according to the embodiments has an excellent rigidity against external impact, which can result in its longer life span.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a plan view of a display device according to a first embodiment;

FIG. 2 is a cross-sectional view taken along line A-A′ of FIG. 1;

FIG. 3 is a cross-sectional view taken along line B-B′ of FIG. 1;

FIGS. 4 and 5 are cross-sectional views of a display device according to a second embodiment;

FIGS. 6 and 7 are cross-sectional views of a display device according to a third embodiment;

FIGS. 8 and 9 are cross-sectional views of a display device according to a fourth embodiment; and

FIG. 10 is a cross-sectional view of a display device according to a fifth embodiment.

### DETAILED DESCRIPTION

Hereinafter, embodiments of the present disclosure will be described with reference to the accompanying drawings. In this specification, when it is mentioned that a component (or region, layer, portion) “is on”, “is connected to”, or “is combined with” another component, terms “is on”, “connected to”, or “combined with” mean that a component may be directly connected to/combined with another component or mean that a third component may be disposed between them.

The same reference numerals correspond to the same components. Also, in the drawings, the thicknesses, ratios, and dimensions of the components are exaggerated for effective description of the technical details. A term “and/or” includes all of one or more combinations that related configurations can define.

While terms such as the first and the second, etc., can be used to describe various components, the components are not limited by the terms mentioned above. The terms are used only for distinguishing between one component and other components. For example, the first component may be designated as the second component without departing from the scope of rights of various embodiments. Similarly, the second component may be designated as the first component. An expression of a singular form includes the expression of plural form thereof unless otherwise explicitly mentioned in the context.

Terms such as “below”, “lower”, “above”, “upper” and the like are used to describe the relationships between the components shown in the drawings. These terms have relative concepts and are described based on directions indicated in the drawings.

Terms used in the present specification are provided for description of only specific embodiments of the present invention, and not intended to be limiting. An expression of a singular form includes the expression of plural form thereof unless otherwise explicitly mentioned in the context. In the present specification, it should be understood that the term “include” or “comprise” and the like is intended to specify characteristics, numbers, steps, operations, components, parts or any combination thereof which are mentioned in the specification, and intended not to previously exclude the possibility of existence or addition of at least one another characteristics, numbers, steps, operations, components, parts or any combination thereof.

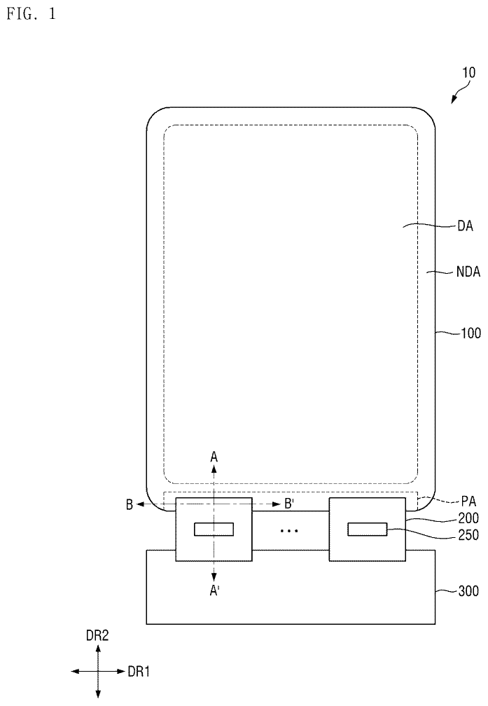

FIG. 1 is a plan view of a display device according to a first embodiment.

Referring to FIG. 1, a display device 10 according to the first embodiment may be an organic light emitting display device. However, the embodiment is not limited thereto. The display device 10 may be a liquid crystal display device or an inorganic light emitting display device. Hereinafter, the description will focus on the fact that the display device according to the embodiment is an organic light emitting display device. The organic light emitting display device may include a display panel 100. The display panel 100 may include a display area (DA) and a non-display area (NDA) located around the display area (DA).

The display area (DA) may include a plurality of pixels. The plurality of pixels may be arranged in a matrix form, and is not limited thereto. The display area (DA) may have a rectangular shape including short sides extending in a first direction DR1 and long sides extending in a second direction DR2, and is not limited thereto.

The non-display area (NDA) may surround the display area (DA) in a planar view. The non-display area (NDA) may include a pad area (PA). The pad area (PA) may be disposed on the other end of the display panel 100 in the second direction DR2. However, the pad area (PA) is not limited to this.

A printed circuit film 200 may be attached on the pad area (PA). A driving chip 250 may be mounted on the printed circuit film 200. A printed circuit board 300 may be attached on the other end of the printed circuit film 200 in the second direction DR2. A plurality of the printed circuit films 200 may be provided and arranged in the first direction DR1.

Although not shown in the printed circuit board 300, a power management integrated circuit (PMIC), a controller, etc., may be mounted on the printed circuit board 300. The controller may perform overall control functions related to driving the display panel 100, and may control the operations of the driving chip 250 and a gate drive circuit. The power management integrated circuit may supply various voltages or currents to the driving chip 250, the gate drive circuit, etc., or may control the various voltages or currents to be supplied. The gate drive circuit may be illustratively disposed on the non-display area (NDA) of one side of the display area (DA) in the first direction DR1 or of the other side of the display area (DA) in the first direction DR1, and is not limited thereto.

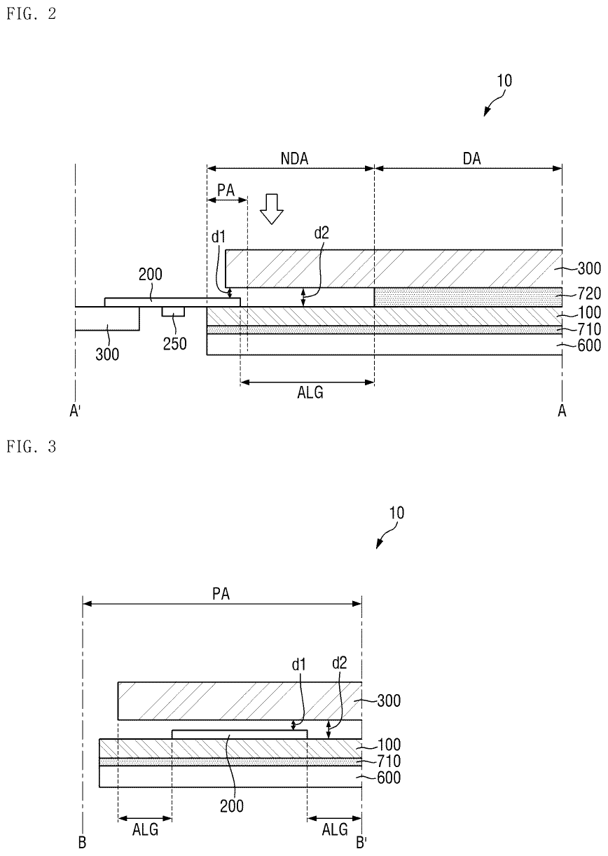

FIG. 2 is a cross-sectional view taken along line A-A′ of FIG. 1. FIG. 3 is a cross-sectional view taken along line B-B′ of FIG. 1. Referring to FIGS. 1 to 3, the display device 10 according to the first embodiment may include a display panel 100, a backplate layer 600 below the display panel 100, and a cover layer 300 above the display panel 100. The display device 10 may further include bonding layers 710 and 720 that bond the adjacent members 100, 300, and 600. The bonding layers 710 and 720 may be disposed between the display panel 100 and the backplate layer 600. The bonding layers 710 and 720 may include the first bonding layer 710 that bonds the display panel 100 and the backplate layer 600, and the second bonding layer 720 that is disposed between the display panel 100 and the cover layer 300 and bonds the display panel 100 and the cover layer 300.

The display panel 100 may include the plurality of pixels (PX) disposed in the display area (DA) of a base substrate. The pixels (PX) may include at least one transistor (TFT) and a light emitting device (OLED) connected to the transistors (TFTs). The transistors (TFTs) controls are turned on or turned off according to a control signal applied through a control signal line, thereby adjusting the amount of current applied to the light emitting device (OLED). The light emitting device (OLED) may emit light with a luminance corresponding to the amount of current applied through the transistor (TFT). The light emitting device (OLED) may include an organic light emitting diode, and is not limited thereto. The base substrate may include a rigid substrate. However, the base substrate is not limited thereto and may include a flexible substrate. When the base substrate of the display panel 100 includes a flexible substrate, the display device 10 may function as a foldable, stretchable, or bendable display device, but is not limited thereto. The display panel 100 may further include a polarization layer, but is not limited to this. The polarization layer may be separately disposed between the display panel 100 and the cover layer 300. The polarization layer may include a first phase retardation layer, a second phase retardation layer on the first phase retardation layer, and a polarization layer on the second phase retardation layer.

The printed circuit film 200 may be attached to the pad area (PA) of the display panel 100.

A backplate layer 600 may be disposed below the display panel 100. The backplate layer 600 may be disposed below the display panel 100 to serve to support the display panel 100. The backplate layer 600 may include a material capable of supporting the display panel 100. For example, the backplate layer 600 may include polyethylene terephthalate (PET), polyimide (PI), or polycarbonate (PC), but is not limited thereto. The backplate layer 600 may be disposed over the display area (DA) and the non-display area (NDA). The side of the backplate layer 600 may be aligned with the side of the display panel 100 thereabove, but is not limited thereto.

The first bonding layer 710 and the second bonding layer 720 may each include an optically clear resin (OCR) or an optically clear adhesive (OCA). The side of the first bonding layer 710 may be aligned with the side of the display panel 100, but is not limited thereto. However, the side of the second bonding layer 720 may be disposed more inside than the side of the display panel 100. The side of the second bonding layer 720 may be disposed within the display area (DA) or may be aligned at the boundary between the display area (DA) and the non-display area (NDA), but is not limited thereto. The side of the second bonding layer 720 may also be aligned in the non-display area (NDA). The side of the second bonding layer 720 is disposed more inside than the side of the display panel 100 because the printed circuit film 200 is attached to the below-described pad area (PA) of the display panel 100. The second bonding layer 720 may not overlap the pad area (PA). The side of the second bonding layer 720 may be disposed within the pad area (PA).

The cover layer 300 may be disposed above the display panel 100. The cover layer 300 may include a rigid material. The rigid material may include glass or a glass material including quartz. The cover layer 300 is disposed above the display panel 100, so that the cover layer 300 may serve to protect members disposed below the cover layer 300 from the outside. The cover layer 300 may be disposed over the display area (DA) and the non-display area (NDA). The cover layer 300 may overlap the printed circuit film 200 in the thickness direction. The side of the cover layer 300 may be disposed more inside than the side of the display panel 100. However, the side of the cover layer 300 is not limited thereto, and may be aligned with the side of the display panel 100 or may extend further outward.

As described above, the printed circuit film 200 may be attached to the pad area (PA) of the display panel 100. The second bonding layer 720 that bonds the cover layer 300 and the display panel 100 may be disposed not to overlap the pad area (PA) in order to prevent physical interference with the printed circuit film 200. As a result, a spaced space (or alignment gap (ALG)) may be formed between the second bonding layer 720 and the printed circuit film 200 in cross-section. The alignment gap (ALG) is located in the non-display area (NDA) and may also overlap the pad area (PA). The thickness of the printed circuit film 200 may be smaller than that of the second bonding layer 720.

Accordingly, in the thickness direction, a spaced space between the cover layer 300 and the printed circuit film 200 may be formed, and a spaced space between the cover layer 300 and the display panel 100 may be formed. The spaced space between the display panel 100 and the cover layer 300 may refer to a spaced space in the alignment gap (ALG). Since the thickness of the printed circuit film 200 is smaller than that of the second bonding layer 720, a spaced distance d1 between the printed circuit film 200 and the cover layer 300 may be smaller than a spaced distance d2 between the display panel 100 and the cover layer 300 in the alignment gap (ALG).

As shown in FIG. 3, the alignment gap (ALG) may be formed on the left or right of the printed circuit film 200. The alignment gaps (ALG) may also be formed in areas between the adjacent printed circuit films 200.

As shown in FIGS. 2 and 3, in the first embodiment, when physical impact is applied from above the display device 10 (or from above the cover layer 300), the spaced space is formed between the cover layer 300 and the members 100 and 200 below the cover layer 300. While the cover layer 300 and the second bonding layer 720 are bonded, the spaced space is formed between the cover layer 300 and the printed circuit film 200 and between the cover layer 300 and the display panel 100 over the alignment gap (ALG). Accordingly, an end portion of the cover layer 300 that is not bonded to the second bonding layer 720 may be very vulnerable to external impact.

The following embodiments propose configurations for compensating for the vulnerability of the end portion of the cover layer 300 to external impact, which is caused by the spaced space formed between the cover layer 300 and the members 100 and 200 below the cover layer 300.

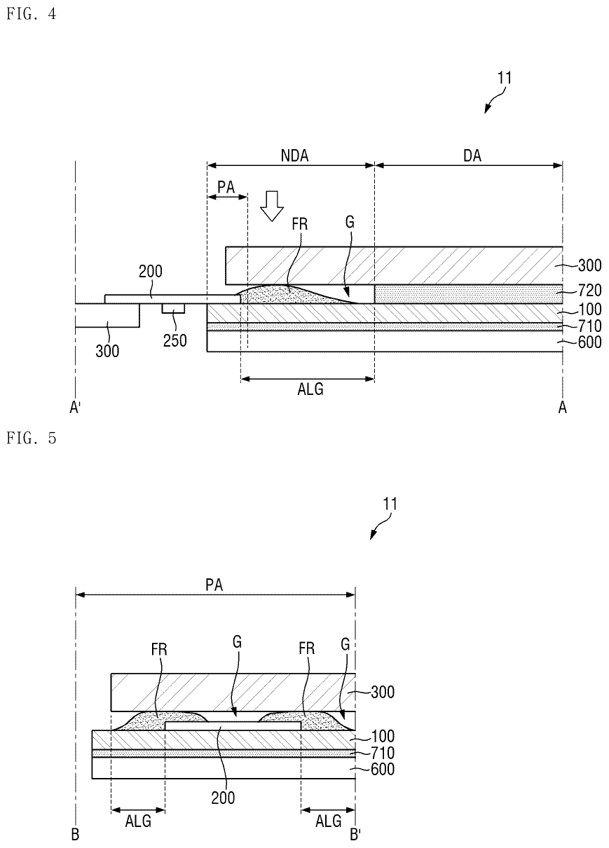

FIGS. 4 and 5 are cross-sectional views of a display device according to a second embodiment.

Referring to FIGS. 4 and 5, a display device 11 according to the second embodiment may further include a filling resin (FR) located in the spaced space between the cover layer 300 and the members 100 and 200 below the cover layer 300. The filling resin (FR) may include resin containing an organic material. The filling resin (FR) fills the spaced space between the cover layer 300 and the members 100 and 200 below the cover layer 300, thereby serving to fill level differences between the members 100, 200, and 720 below the cover layer 300.

However, as shown in FIGS. 4 and 5, the filling resin (FR) may not completely fill the spaced space between the cover layer 300 and the members 100 and 200 below the cover layer 300. This is due to the viscosity of the filling resin (FR). If the viscosity of the filling resin (FR) is lower than a standard range, when the filling resin (FR) is filled in the spaced space between the cover layer 300 and the members 100 and 200 below the cover layer 300 through a gap filling process, the filling resin (FR) with high fluidity flows into the spaced space between the cover layer 300 and the members 100 and 200 below the cover layer 300, so that poor appearance may occur in the display device 11. Also, If the viscosity of the filling resin (FR) is higher than the standard range, when the filling resin (FR) is filled in the spaced space between the cover layer 300 and the members 100 and 200 below the cover layer 300 through the gap filling process, the filling resin (FR) with low fluidity cannot fill the entire spaced space between the cover layer 300 and the members 100 and 200 below the cover layer 300, so that an empty space G may be formed. Since the viscosity of the filling resin (FR) is very sensitive to process conditions such as process temperature during gap filling, it may be very difficult for the viscosity of the filling resin (FR) to meet the standard range.

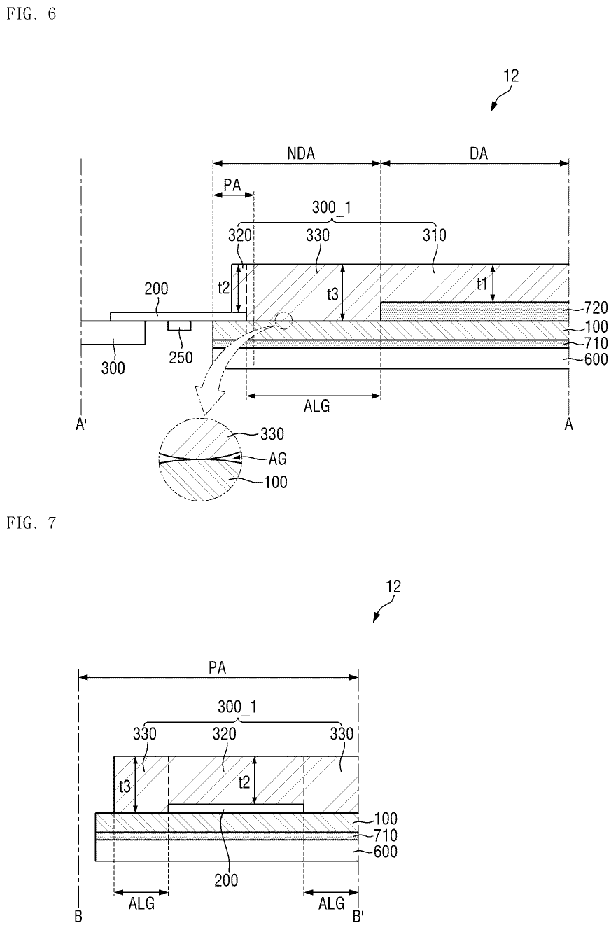

FIGS. 6 and 7 are cross-sectional views of a display device according to a third embodiment.

Referring to FIGS. 6 and 7, a display device 12 according to the third embodiment is different from the display device 10 of FIGS. 2 and 3 in that a cover layer 300_1 has different thicknesses t1, t2, and t3 for each area.

More specifically, the cover layer 300_1 may include a first portion 310 having the first thickness t1, a second portion 320 having the second thickness t2, and a third portion 330 having the third thickness t3. The first portion 310 may overlap the second bonding layer 720 and may come in contact with the second bonding layer 720. The second portion 320 may overlap the printed circuit film 200 and may come in contact with the printed circuit film 200. The third portion 330 may overlap the alignment gap (ALG) and may come in contact with the display panel 100 over the alignment gap (ALG). The first to third portions 310 to 330 of the cover layer 300_1 may include the same material and may be directly connected to each other.

As described above in FIG. 3, the spaced space between the cover layer 300 and the printed circuit film 200 may be formed, and the spaced space between the cover layer 300 and the display panel 100 over the alignment gap (ALG) may be formed. Also, the spaced distance d1 between the printed circuit film 200 and the cover layer 300 may be smaller than the spaced distance d2 between the display panel 100 and the cover layer 300 in the alignment gap (ALG). However, according to the display device 12 of the third embodiment, considering the spaced distances between the cover layer 300_1 and the members 100, 200, and 730 below the cover layer 300_1, the thicknesses t1, t2, and t3 of the cover layer 300_1 are designed differently for each area to fill the spaced space between the cover layer 300 and the members 100 and 200 below the cover layer 300.

According to the cover layer 300_1 of the display device 12 according to the third embodiment, the thicknesses t1, t2, and t3 of the cover layer 300_1 are designed differently for each area, and the spaced space between the cover layer 300 and the members 100 and 200 below the cover layer 300 is filled, so that it is possible to solve the problem that the end portion of the cover layer 300_1 that is not bonded to the second bonding layer 720 is very vulnerable to external impact.

Meanwhile, as shown in FIG. 6 and the enlarged view of FIG. 6, an air gap (AG) may be formed between the bottom surface of the cover layer 300_1 and the members 100 and 200 below the cover layer 300_1. This is because unevenness may be formed on the bottom surface of the cover layer 300_1 during an etching process for forming the first to third portions 310, 320, and 330 of the cover layer 300_1.

That is, according to the display device 12 of FIGS. 6 and 7, the thicknesses t1, t2, and t3 of the cover layer 300_1 are designed differently for each area, and the spaced space between the cover layer 300 and the members 100 and 200 below the cover layer 300 can be filled. However, due to the unevenness shape on the bottom surface of the cover layer 300_1, it may not be possible to completely fill the spaced space between the cover layer 300_1 and the members 100 and 200 below the cover layer 300_1. When external air is introduced or moisture permeation occurs through the air gap (AG) formed between the bottom surface of the cover layer 300_1 and the members 100 and 200 below the cover layer 300_1, defects may be caused in the display device 12.

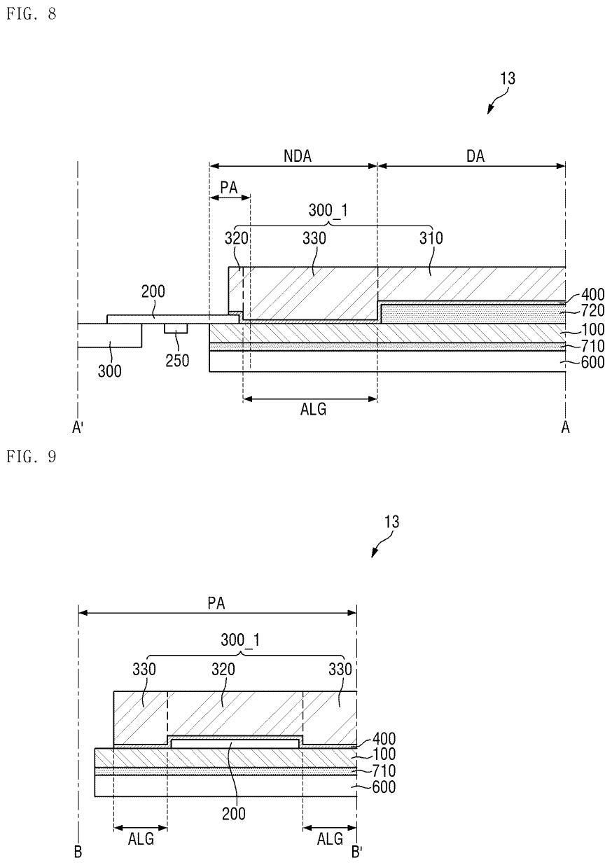

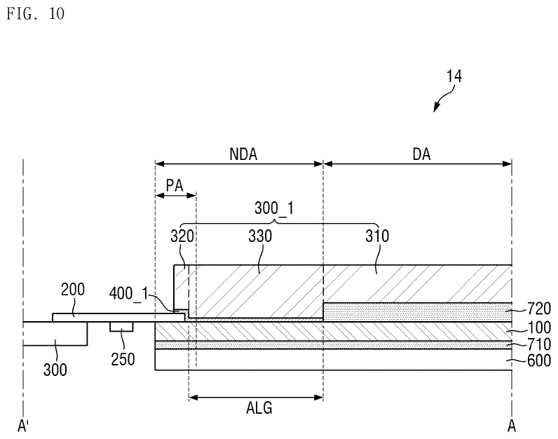

FIGS. 8 and 9 are cross-sectional views of a display device according to a fourth embodiment.

Referring to FIGS. 8 and 9, a display device 13 according to the fourth embodiment may further include a resin layer 400 disposed between the cover layer 300_1 and the members 100, 200, and 720 below the cover layer 300_1.

More specifically, the resin layer 400 may be formed by being coated on the bottom surface of the cover layer 300_1. The resin layer 400 may include a resin containing an organic material. The resin layer 400 may be formed on the bottom surfaces of the first to third portions 310, 320, and 330, and may come in contact with the top surface of the printed circuit film 200, the top surface of the display panel 100 over the alignment gap (ALG), and the top surface of the second bonding layer 720, respectively.

As described above in FIG. 6, according to the display device 12 of FIGS. 6 and 7, the thicknesses t1, t2, and t3 of the cover layer 300_1 are designed differently for each area, and the spaced space between the cover layer 300 and the members 100 and 200 below the cover layer 300 can be filled. However, due to the unevenness shape on the bottom surface of the cover layer 300_1, it may not be possible to completely fill the spaced space between the cover layer 300_1 and the members 100 and 200 below the cover layer 300_1. That is, the cover layer 300_1 includes a rigid material. Therefore, even if the cover layer 300_1 is strongly pressed from above, the spaced space between the bottom surface of the cover layer 300_1 including the rigid material and the members 100 and 200 below the cover layer 300_1 cannot be completely filled.

However, according to the display device 13 of FIGS. 8 and 9, the resin layer 400 is formed by being coated on the bottom surface of the cover layer 300_1. The resin layer 400 may include a material with a lower modulus than that of the cover layer 300_1 including a rigid material. That is, the resin layer 400 including a material with a lower modulus than that of the cover layer 300_1 is additionally formed on the bottom surface of the cover layer 300_1, so that the spaced space between the bottom surface of the cover layer 300_1 and the members 100 and 200 below the cover layer 300_1 can be completely filled.

Therefore, in the display device 13 according to the fourth embodiment, the resin layer 400 is additionally formed on the bottom surface of the cover layer 300_1. Therefore, when external air is introduced or moisture permeation occurs through the air gap (AG) formed between the bottom surface of the cover layer 300_1 and the members 100 and 200 below the cover layer 300_1, defects can be prevented in advance from being caused in the display device 12.

FIG. 10 is a cross-sectional view of a display device according to a fifth embodiment.

Referring to FIG. 10, a display device 14 according to the fifth embodiment is different from the display device 13 according to FIGS. 8 and 9 in that a resin layer 400_1 is not formed on the first portion 310.

Since other descriptions have been made above in FIGS. 8 and 9, detailed descriptions thereof will be omitted below.

The display device according to some embodiments includes: a display panel configured to include a display area and a pad area around the display area; a printed circuit film configured to be attached to the pad area of the display panel; a cover layer configured to be disposed above the display panel and to overlap the printed circuit film; and a bonding layer configured to bond the display panel and the cover layer. The printed circuit film and the bonding layer have a spaced space between each other in a planar view. A thickness of the cover layer that overlaps the printed circuit film has a size between a thickness of the cover layer in the spaced space and a thickness of the cover layer on the bonding layer.

The thickness of the cover layer in the spaced space may be larger than the thickness of the cover layer that overlaps the printed circuit film.

The cover layer may include a rigid material.

A side of the display panel may protrude more outward than a side of the cover layer.

The cover layer may come in direct contact with a top surface of the printed circuit film and a top surface of the display panel in the spaced space.

An air gap may be formed either between the cover layer and a top surface of the printed circuit film or between the cover layer and a top surface of the display panel in the spaced space.

The cover layer may further include a resin layer coated on a bottom surface thereof.

The resin layer may be disposed on a bottom surface of the cover layer overlapping the printed circuit film and on a bottom surface of the cover layer in the spaced space.

A display device according to some embodiments includes: a display panel configured to include a display area and a pad area around the display area; a printed circuit film configured to be attached to the pad area of the display panel; a cover layer configured to be disposed above the display panel and to overlap the printed circuit film; and a bonding layer configured to bond the display panel and the cover layer. A thickness of the cover layer varies depending on the areas.

The cover layer may include a first portion overlapping the bonding layer, a second portion overlapping the printed circuit film, and a third portion overlapping a spaced space.

The thickness of the second portion may have a size between a thickness of the first portion and a thickness of the third portion, and the thickness of the third portion may be larger than the thickness of the second portion.

The cover layer may include a rigid material.

A side of the display panel may protrude more outward than a side of the cover layer.

The second portion may come in direct contact with a top surface of the printed circuit film, and the third portion may come in direct contact with a top surface of the display panel in the spaced space.

An air gap may be formed either between the second portion and a top surface of the printed circuit film or between the third portion and a top surface of the display panel in the spaced space.

The cover layer may further include a resin layer coated on a bottom surface thereof.

The resin layer may be disposed on a bottom surface of the second portion and on a bottom surface of the third portion.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

### REFERENCE NUMERALS

10, 11: Display Device
100: Display Panel
200: Printed Circuit Film
300, 300_1: Cover Layer
400, 400_1: Resin Layer
710: First Bonding Layer
720: Second Bonding Layer

What is claimed is:

1. A display device, comprising:
a display panel configured to include a display area and a pad area around the display area;
a printed circuit film configured to be attached to the pad area of the display panel;
a cover layer configured to be disposed above the display panel and to overlap the printed circuit film; and
a bonding layer configured to bond the display panel and the cover layer,
wherein the printed circuit film and the bonding layer have a spaced space between each other in a planar view, and
wherein a thickness of the cover layer that overlaps the printed circuit film has a size between a thickness of the cover layer in the spaced space and a thickness of the cover layer on the bonding layer.

2. The display device of claim 1, wherein the thickness of the cover layer in the spaced space is larger than the thickness of the cover layer that overlaps the printed circuit film.

3. The display device of claim 1, wherein the cover layer comprises a rigid material.

4. The display device of claim 1, wherein a side of the display panel protrudes more outward than a side of the cover layer.

5. The display device of claim 1, wherein the cover layer comes in direct contact with a top surface of the printed circuit film and a top surface of the display panel in the spaced space.

6. The display device of claim 1, wherein an air gap is formed either between the cover layer and a top surface of the printed circuit film or between the cover layer and a top surface of the display panel in the spaced space.

7. The display device of claim 1, further comprising a resin layer coated on a bottom surface of the cover layer.

8. The display device of claim 7, wherein the resin layer is disposed on a bottom surface of the cover layer overlapping the printed circuit film and on a bottom surface of the cover layer in the spaced space.

9. A display device, comprising:
a display panel configured to include a display area and a pad area around the display area;
a printed circuit film configured to be attached to the pad area of the display panel;
a cover layer configured to be disposed above the display panel and to overlap the printed circuit film; and
a bonding layer configured to bond the display panel and the cover layer,
wherein a thickness of the cover layer varies depending on the areas.

10. The display device of claim 9, wherein the cover layer comprises a first portion overlapping the bonding layer, a second portion overlapping the printed circuit film, and a third portion overlapping a spaced space.

11. The display device of claim 10, wherein a thickness of the second portion has a size between a thickness of the first portion and a thickness of the third portion, and the thickness of the third portion is larger than the thickness of the second portion.

12. The display device of claim 10, wherein the cover layer comprises a rigid material.

13. The display device of claim 10, wherein a side of the display panel protrudes more outward than a side of the cover layer.

14. The display device of claim 10, wherein the second portion comes in direct contact with a top surface of the printed circuit film, and the third portion comes in direct contact with a top surface of the display panel in the spaced space.

15. The display device of claim 10, wherein an air gap is formed either between the second portion and a top surface of the printed circuit film or between the third portion and a top surface of the display panel in the spaced space.

16. The display device of claim 10, further comprising a resin layer coated on a bottom surface of the cover layer.

17. The display device of claim 16, wherein the resin layer is disposed on a bottom surface of the second portion and on a bottom surface of the third portion.
